(19) United States
(12) Patent Application Publication
(10) Pub. No.: US 2025/0384318 A1
(43) Pub. Date: Dec. 18, 2025

(54) MICROMAGNETIC DESIGN FOR SCALABLE QUBIT CONFIGURATION

(71) Applicant: TECHNISCHE UNIVERSITEIT DELFT, Delft (NL)

(72) Inventor: Alexander Sergeyevich Ivlev, Delft (NL)

(21) Appl. No.: 18/877,727

(22) PCT Filed: Jun. 15, 2023
(86) PCT No.: PCT/NL2023/050335

§ 371 Date: Dec. 20, 2024

(30) Foreign Application Priority Data
Jun. 24, 2022 (NL) 2032280

(51) Int. Cl. G06N 10/40; G06N 10/20; G06N 10/70

(52) U.S. Cl. CPC G06N 10/40; G06N 10/20; G06N 10/70

(57) ABSTRACT

A quantum dot structure comprises a two-dimensional quantum dot array and a micromagnet array comprising a plurality of micromagnets arranged in a periodic micromagnet configuration. The plurality of micromagnets form a magnetic field comprising local maxima and local minima in a plane defined by the two-dimensional quantum dot array. Each of a first part of the quantum dots is located at a local maximum of the magnetic field and each of a second part of the quantum dots is located at a local minimum of the magnetic field. The micromagnet configuration can form a tessellation of the quantum dot structure based on a wallpaper group.

### CROSS-REFERENCE TO RELATED APPLICATION(S)

This Application is a Section 371 National Stage Application of International Application No. PCT/NL2023/050335, filed Jun. 15, 2023 and published as WO 2023/249486 A1 on Dec. 28, 2023, in English, the contents of which are hereby incorporated by reference in their entirety.

### TECHNICAL FIELD

The disclosure relates to quantum dot structures, and in particular, though not exclusively, to micromagnets configurations for scalable quantum dot structures.

### BACKGROUND

Quantum computing is fundamentally different than classical computing. The quantum computer's structure gives access to quantum-mechanical properties such as superposition and entanglement which are not available to classical computers. For certain problems, quantum computers offer drastic computational speed-up, ranging from quadratic acceleration of searching unstructured data, to exponential improvements for factoring large numbers used in encryption applications. Quantum computing is based on qubits. Qubits can be formed, for example, by a single electron spin in a so-called quantum dot.

One promising way to control these qubits is Electric Dipole Spin Resonance (EDSR). EDSR is a method to control the magnetic moments inside a material using quantum mechanical effects like the spin-orbit interaction. Mainly, EDSR allows to flip the orientation of the magnetic moments through the use of electromagnetic radiation at resonant frequencies. These resonant frequencies depend on the local magnetic field strength.

Systems with larger amounts of (interconnected) qubits can execute more complicated algorithms, or can execute algorithms more efficiently than systems with fewer qubits. Practically speaking, these qubits are arranged on a two-dimensional array. However, current designs for qubit arrays are typically poorly scalable in more than one dimension. It is therefore desirable to create scalable two-dimensional arrays for individually addressable qubits.

Spin-based quantum dots are created by applying a magnetic field over the qubit, e.g., using micromagnets, in order to introduce a Zeeman split between spin states. Thus, the qubits can be controlled through EDSR using electromagnetic waves with a frequency that is tuned to the Zeeman split. In order to be able to address qubits in a qubit array individually, they either need to be spaced apart relatively far away from each other, limiting interacting between neighboring qubits (crosstalk), or they need to have different magnetic field strengths, and hence different resonance frequencies.

However, in order to reduce or prevent noise, the magnetic field around each qubit needs to be symmetric and the gradient of the magnitude of the magnetic field should be minimized. These requirements conflict with the requirement of having sufficiently different magnetic fields in neighboring qubits.

Shota lizuka et al., ‘Buried nanomagnet realizing high-speed/low-variability silicon spin qubits: implementable in error-correctable large-scale quantum computers’, 2021 Symposium on VLSI Circuits (JSAP, 2021) describes a method for fabricating a semiconductor quantum dot structure comprising buried nanomagnets.

WO 2020/188240 A1 describes a device for quantum information processing. The device comprises a first plurality of confinement regions for confining spinful charge carriers for use as data qudits. The device further comprises a second plurality of confinement regions for confining spinful charge carriers for use as ancilla qudits. Micromagnets may be positioned at the data dots but not at the ancilla dots, resulting in a large Zeeman splitting gradient between the data dots and the ancilla dots.

Hence, from the above, it follows that there is a need in the art for a two-dimensional scalable qubit array which increases addressability and decreases noise.

### SUMMARY

It is an aim of embodiments in this disclosure to provide a system that avoids, or at least reduces the drawbacks of the prior art.

In a first aspect, this disclosure relates to a quantum dot structure comprising a two-dimensional quantum dot array and a micromagnet array comprising a plurality of micromagnets arranged in a periodic micromagnet configuration. The plurality of micromagnets form a magnetic field comprising local maxima and local minima in a plane defined by the two-dimensional quantum dot array. Each of a first part of the quantum dots is located at a local maximum of the magnetic field and each of a second part of the quantum dots is located at a local minimum of the magnetic field.

The local maxima and local minima may be local maxima and local minima of a longitudinal component of the magnetic field. In some embodiments, the magnetic field may also comprise a transversal component which may not have a local maximum or local minimum at the quantum dots.

It is understood that the magnetic field is not constant over space, such that the local maxima and minima are distinct. The local maxima and local minima refer to the magnitude of the magnetic field. The magnetic field strength in the first part of the quantum dots is different from the magnetic field strength in the second part of the quantum dots, improving the addressability. In the local maxima and minima of the magnetic field, the first derivative of the magnitude of the magnetic field in the x,y-plane is substantially zero, suppressing noise.

The plane defined by the two-dimensional quantum dot array may be referred to as the x,y-plane. The two-dimensional quantum dot array is typically a regular array, e.g., a regular triangular or parallelogrammatic array. The micromagnet array is also typically a regular array, e.g., a regular triangular or parallelogrammatic array. Thus, the plurality of micromagnets may be arranged such that the quantum dots are located at vertices of the micromagnet array, such that a magnitude of a magnetic field generated by the micromagnets is different for each vertex of a triangle (for a regular triangular array) or parallelogram (for a regular parallelogrammatic array). In an embodiment, the configuration of the micromagnets forms a tessellation of the quantum dot structure based on a wallpaper group.

The quantum structure may comprise at least 16, at least 32, at least 64, at least 96, or even more quantum dots, e.g., hundreds or even thousands.

In an embodiment, the magnetic field comprises saddle points in the plane defined by the two-dimensional quantum dot array. In such an embodiment, each of a third part of the quantum dots is located at a saddle point of the magnetic field. The magnitude of the magnetic field in a saddle point is different from the magnitude in the nearest local minimum and nearest local maximum. The first derivative of the magnitude of the magnetic field in a saddle point is substantially zero.

As used herein, individual addressability of quantum dots refers to the possibility to address a quantum dot without disturbing other (neighboring) quantum dots. Thus, for a quantum dot to be individually addressable, the magnitude of the magnetic field in the quantum dot should be different from the magnitude of the magnetic field in, at least, the nearest neighbor quantum dots.

Generally, each quantum dot may house a qubit. In order for two (nearby) qubits in two quantum dots to be individually addressable, the magnetic field strength, i.e., the magnitude of the magnetic field, at the two qubits should be different. The amount with which the magnetic field strengths in different quantum dots should differ depends on the characteristics of the implementation, e.g., the distance between neighboring quantum dots. At the same time, the derivative (gradient) of the magnitude of the magnetic field (or magnetic field strength) in the plane defined by the qubit-containing layer should be as close to zero as possible, in order to reduce noise and/or decoherence of the qubit; for example, the quantum dot should be positioned at or near a local minimum, a local maximum, or a saddle point of the magnitude of the magnetic field. This way, a small movement of the charge carrier forming the qubit within the quantum dot region does not substantially affect the magnitude of the magnetic field experienced by the charge carrier, and hence the qubit's resonance frequency (or ‘addressation frequency’). In an embodiment, the magnetic field strength has at least a two-fold rotational symmetry around the qubits. The use of a regular or semi-regular tessellation ensures scalability of the design.

This way, the micromagnets may create a magnetic field at each quantum dot region that allows individual addressability of the qubit, while the symmetry around each quantum dot, and hence the small decoherence gradient, reduces the noise.

As used herein, the term ‘micromagnet’ refers to any magnetizable matter with dimensions of less than about 10 μm. In practice, the size of the micromagnets depends on the configuration of the quantum dot array; size of less than 1 μm or even less than 0.1 μm are common. Micromagnets smaller than 1 μm may sometimes be referred to as nanomagnets. Typically, the micromagnets are paramagnets that are magnetized by an external magnetic field. The micromagnets may comprise cobalt. In some cases, the micromagnets consist essentially entirely of cobalt, but other alloys are also possible. Typically, the magnitude of the magnetic field only or mainly differs in the direction of the external magnetic field. Typically, the micromagnets are provided in one or more layers above or below the layer or plane comprising the quantum dot regions.

In an embodiment, the micromagnets have a width between about 10-100 nm, between 20-80 nm, or between 30-60 nm, a length between about 10-200 nm, between 20-150, between 25-100 nm, or between 30-80 nm, and a thickness (height) between about 5-100 nm or between about 10-50 nm, for example about 30 nm. Where non-rectangular micromagnets are used, the above measurements may relate to similar dimensions, e.g., the length, width of a rectangular bounding box of the micromagnet.

In an embodiment, a distance between two (neighboring) quantum dots in the quantum dot array is smaller than 200 nm, smaller than 150 nm, or smaller than 100 nm. For example, the distance may be about 90 nm or 80 nm, or even smaller. In general, the length and width of the micromagnet are smaller than the distance between two neighboring quantum dots.

In an embodiment, the two-dimensional quantum dot array is formed in a stack of one or more semiconductor layers arranged on a substrate. The quantum dot structure may further comprise a plurality of electrodes. The plurality of electrodes may be arranged to create and/or adjust an electric field, preferably a time-varying electric field, in the quantum dot structure. For example, the plurality of electrodes may be arranged to create and control qubits, e.g., Electric Dipole Spin Resonance (EDSR) controllable qubits, in the two-dimensional quantum dot array. However, other means of manipulating charge carriers, and in particular the spin of the charge carriers (e.g., to control qubits) are not excluded.

Different embodiments may use different kinds of quantum dots, e.g., nitrogen-induced defects in e.g. semiconductor materials, nitrogen-vacancy centers in diamond, 2DEG-based quantum dots, et cetera. In principle, the micromagnet configurations described herein may be applied to any quantum dot structure where a difference in magnetic field magnitude between neighboring quantum dots is desired.

In an embodiment, the micromagnet configuration defines a locally rotationally symmetric array of micromagnets. Thus, each quantum dot may be located in a rotation center of the rotationally symmetric array of micromagnets. A rotation center is sometimes referred to as a rotocenter. It can be shown that due to the rotational symmetry, the gradient of the magnitude of the magnetic field vanishes, thus suppressing noise.

In an embodiment, the micromagnet configuration is based on a wallpaper group. For example, the plurality of micromagnets may form a regular triangular or hexagonal micromagnet grid and the configuration of the micromagnets may be based on a p3 or a p3m1 wallpaper group. As a different example, the plurality of micromagnets may form a parallelogrammatic or hexagonal micromagnet grid and the configuration of the micromagnets may be based on a p2 or a pmm wallpaper group. In such an embodiment, each fundamental domain of the wallpaper group may comprise at least part of a micromagnet.

It has been shown that the p3 and a p3m1 wallpaper groups are the only tessellations with threefold rotational symmetry and three distinct symmetry centers. By positioning the quantum dot regions in the symmetry centers, the first derivative of the magnitude of the magnetic field in the symmetry centers can be minimized, while the magnitude of the magnetic field can be chosen to be different for each of the three distinct symmetry centers. Similarly, the pmm and p2 wallpaper groups are the only tessellations with four distinct symmetry centers, which may be chosen to correspond to four distinct field strengths per primitive cell (tile), while the first derivative is again minimized in the symmetry centers. Therefore, locally, these tessellations leads to the highest addressability and lowest noise. By tiling the pattern, an arbitrarily large quantum dot array may be obtained. An advantage of the pmm and p2 groups is that they have four distinct symmetry centers, and hence four distinct magnetic field magnitudes at the quantum dot regions, compared to three for the p3m1 and p3 groups. An advantage of the pmm and p3m1 groups is that they have a higher degree of symmetry than the p2 and p3 groups, respectively, having additional reflection symmetries. This higher degree of symmetry may lead to a lower noise susceptibility. An advantage of the p2 and p3 groups is that they allow for more flexible positioning of the quantum dot regions and may require fewer or less complex micromagnets than the pmm and p3m1 groups, respectively.

A tessellation based on one of the above-mentioned wallpaper groups is based on a primitive cell with the form of a parallelogram. In principle, the tessellation comprises copies of the primitive cell which are translated along the edges of the parallelogram. Each primitive cell comprises two or more copies of a fundamental domain, which are rotated and/or mirrored (reflected) with respect to each other. For example, each primitive cell of a p2-based tessellation comprises two fundamental domains, and each primitive cell of a pmm-based tessellation comprises four fundamental domains. In general, each fundamental domain comprises at least a (part of a) micromagnet. The micromagnet grid refers to the grid defined by the fundamental domains.

In an embodiment, the micromagnet grid is a rectangular grid and each fundamental domain comprises a micromagnet positioned along a diagonal of the fundamental domain. This is an efficient manner to create the desired magnetic fields.

In an embodiment, the plurality of micromagnets comprises a first micromagnet generating a first magnetic field and a second micromagnet generating a second magnetic field different from the first magnetic field, such that the difference between the first and second magnetic fields is small compared to both the first and second magnetic fields. The first and second micromagnets, or parts of micromagnets, may differ in, e.g., magnetization, shape, and/or position. The first and second micromagnets may be positioned in neighboring fundamental domains. This way, small deviations from an ‘ideal’ or ‘pure’ wallpaper group may be obtained, which may increase the area in which resonant frequencies are sufficiently different from each other, while still keeping noise levels as low as possible. A group of micromagnets with different magnetic fields may define a tile, and the quantum dot array may be covered with a tessellation of these tiles.

In an embodiment, a difference in magnetic field strength between neighboring quantum dots is larger than 0.1 mT and/or such that a difference in resonant frequency between neighboring quantum dots is at least 2 MHz. In some embodiment, the difference in magnetic field strength between neighboring quantum dots may be at least 0.2 mT, or at least 0.3 mT and/or the difference in resonant frequency between neighboring quantum dots may be at least 5 MHz, or larger than at least 10 MHz

In order to achieve desired control with current equipment limitations, a bandwidth (energy difference between the qubits) of at least 2 MHz is desired, but a larger bandwidth, such as 5 MHz or 10 MHz may reduce requirements for other components. The corresponding magnetic field difference depends on the specifics of the quantum chip, but for, e.g., silicon (a much used material for such chips), a 10 MHz bandwidth translates to a difference of at least about 0.35 mT.

In an embodiment, the magnetic field gradient at the quantum dot locations is at most 0.1 mT/nm, for example, at most 0.05 mT/nm or 0.03 mT/nm. This way, noise may be effectively suppressed.

The quantum dot structure may comprise two or more types of quantum dots, for example data dots and ancilla dots. In some embodiments, not all types of quantum dots need to be individually addressable; for example, the data dots may need to be addressable while the ancilla dots do not. In such embodiments, the positions of the non-individually-addressable quantum dots need not correspond to (approximate) symmetry centers of the micromagnet configuration.

### BRIEF DESCRIPTION OF THE DRAWINGS

FIGS. 1A and 1B depict schematics of a cross-section of a typical large-area two-dimensional quantum dot structure and FIG. 1C-1E schematically depict magnetic fields in such a quantum dot structure;

FIGS. 2A and 2B schematically depict a prior-art micromagnet configuration;

FIGS. 3A and 3B schematically depict a micromagnet configuration according to an embodiment;

FIG. 4A-E schematically depict application of a pmm-wallpaper-group based micromagnet configuration to a quantum dot array according to an embodiment;

FIG. 5A-D schematically depict various wallpaper groups;

FIG. 6A-F schematically depict quantum dot arrays according to various embodiments;

FIG. 7A-C schematically depict micromagnet configurations according to various embodiments;

FIGS. 8A and 8B schematically depict a micromagnet configuration according to an embodiment;

FIGS. 9A and 9B schematically depict a 3D configuration and a cross-section, respectively, of a chip according to an embodiment; and

FIG. 10 depicts simulated measurements on a chip according to an embodiment.

### DETAILED DESCRIPTION

The embodiments in this disclosure aim to provide a scalable two-dimensional array of quantum structures, e.g. quantum dots, formed in one or more semiconductor layers, wherein a local magnetic field in the quantum structures is generated or modified at least in part using micromagnets. In particular, the embodiments in this disclosure describe micromagnet configurations for quantum dot arrays enabling individually addressable quantum dots while keeping noise levels low. Individual addressability of quantum structures is important for providing an array of quantum structures in which each quantum structure can be reliably operated as a qubit. The examples hereunder are described with reference to gate-induced and lateral gate-defined quantum dot structures in semiconductors, and in particular to EDSR-controlled qubits; however, it is submitted that embodiments not limited to such quantum dot structures are also envisaged. In general, the described micromagnet configurations can be applied to any type of quantum structure that is sensitive to local magnetic fields and/or local magnetic field gradients.

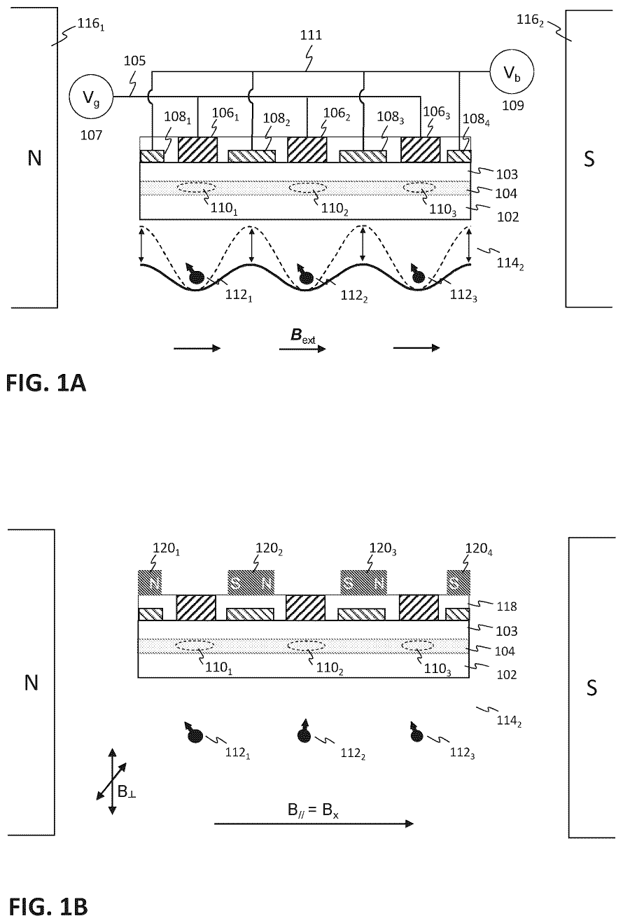

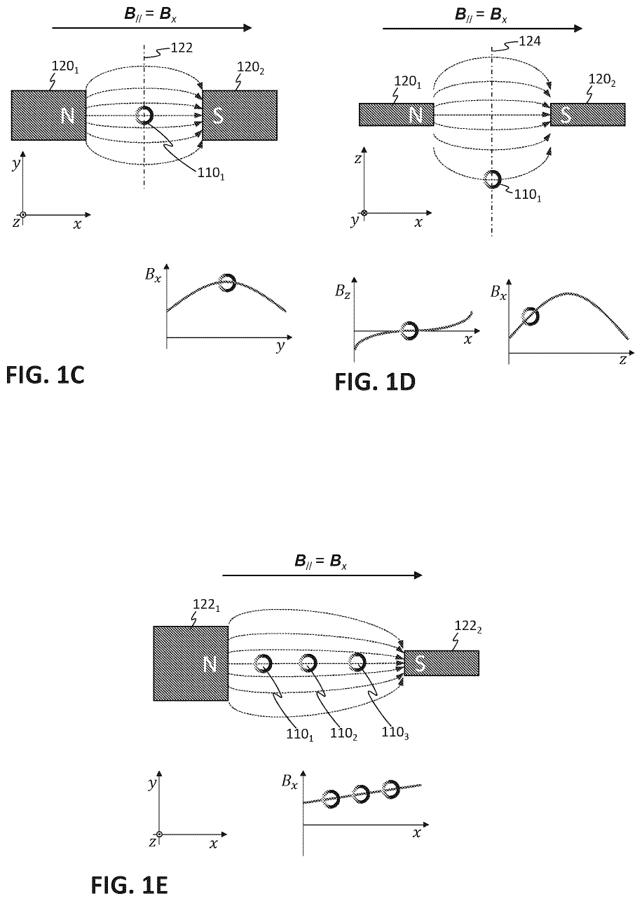

FIGS. 1A and 1B depict schematics of a cross-section of a typical large-area two-dimensional quantum dot structure, and FIG. 1C-1E schematically depict magnetic fields in such a quantum dot structure. The quantum dot structure comprises an array of quantum dot regions 11013 which can be configured, for example, as qubits. Quantum dots are tiny regions of conducting material in an environment of insulating material. Different types of quantum dots may be envisaged, e.g., quantum dots formed in a stack of semiconductor layers 104 in which a two-dimensional electron gas (2DEG) or a two-dimensional hole gas (2DHG) is formed, i.e., a thin (˜10 nm) sheet of electrons or holes that can only move along an interface between two semiconductor layers. The quantum dots can be defined in this 2D electron or hole gas using electric charges applied by gates. Because of the small size of these quantum dots (lateral size 10-100 nm), it takes a finite charging energy to add an extra charge carriers (e.g., electron or hole) to the quantum dot, due to Coulomb repulsion. A sufficiently large charging energy allows to control the number of electrons (or holes) confined in a quantum dot accurately down to the single-electron regime. For ease of reference, the following generally assumes a electrons in a 2DEG, but is equally applicable to holes in a 2DHG.

Furthermore, the small size of the quantum dots also causes the orbital levels of electrons in the quantum dots to be quantized, leading to behaviour that is similar to electron shells in atoms. The quantum states of a quantum dot, e.g. the spin state of a single charge carrier such as an electron or a hole in the quantum dot, may be used to configure and operate a quantum dot as a qubit. Quantum dots with more than two quantum states may be operated as qudits (having d quantum states, d being an integer number larger than 1), e.g., qutrits (having 3 quantum states). Although the examples presented herein primarily refer to qubits, other quantum dot usages are similarly envisaged.

To create lateral gate-defined quantum dots, first a two-dimensional electron gas (2DEG) is formed by confinement at an interface in a heterostructure. Band gap differences between materials in the heterostructure result in strong confinement in the vertical direction, which yields quantization of the electron motion perpendicular to the interface. The 2DEG may be supplied with electrons from a doping layer in the heterostructure (depletion-mode quantum dots) or induced by accumulation gates (accumulation-mode quantum dots). An example of such a system is gallium arsenide/aluminium gallium arsenide (GaAs/AlGaAs). Suitable silicon-compatible systems for forming quantum structures include silicon-germanium heterostructures and silicon metal-oxide-semiconductor (SIMOS) structures. Examples of such structures are described in the article by Lawrie et al, Quantum Dot Arrays in Silicon and Germanium, Appl. Phys. Lett. 116, 080501 (2020), which is hereby incorporated by reference.

For example, in an embodiment, the semiconductor layer stack may include a Silicon substrate, an intrinsic Silicon layer, an isotopically purified Silicon (²⁸Si) epitaxial layer and a SiO₂ layer. In another embodiment, the semiconductor layer stack may include a Si/SiGe heterostructure formed on a Silicon substrate, wherein the Si/SiGe heterostructure may include a graded Si₁₋ₓGe, layer and an isotopically purified Silicon (²⁸Si) epitaxial layer between two SiGe layers. In another embodiment, the semiconductor layer stack may include a Ge/SiGe heterostructure formed on a Silicon substrate, wherein the Ge/SiGe heterostructure includes a Germanium layer formed on the Silicon substrate followed by a reversed graded Si₁₋ₓGe, and a Ge epitaxial layer between two SiGe layers. Other suitable systems for forming quantum structures include nanowires, hut wires, self-assembled quantum dots, etc.

After forming the 2DEG, fine gate electrodes on top of the heterostructure allow to locally tune the potential landscape in the 2DEG by setting the gate voltages, thereby forming quantum dots that are isolated from other dots and the reservoirs by tunnel barriers. The regions in which quantum dots may be formed by application of a voltage, may be referred to as quantum dot regions. The same gate electrodes can be used to control the number of electrons in the quantum dots. A quantum dot array comprises a plurality of such quantum dots. Each quantum dot may be created in a quantum dot region. The quantum dot regions may be arranged, for example, in a regular array of k rows and/columns (with k and/being integer numbers larger than one). The structure may be described using a Cartesian coordinate system, wherein conventionally, the in-plane coordinates are defined as the x and y coordinates.

In the example depicted in FIG. 1A, the quantum dot structure further comprises electrodes wherein each electrode controls a plurality of quantum dots, e.g. a row (or column) of quantum dots, in the quantum dot array. In other embodiments, each gate may be controlled by a dedicated electrode; more complicated arrangements are also contemplated. It is noted that the figure only shows a small part of the quantum dot array, which may comprise a large number of quantum dot regions 1101-3. The figure includes one or more semiconductor layers 104 arranged on a substrate 102. The electrode structures for forming and controlling a plurality of quantum dot regions in the one or more semiconductor layers may be formed over the one or more semiconductor layers. The substrate and the one or more semiconductor layers may form a layered semiconductor stack that is suitable for the formation of quantum dot arrays.

The electrodes structures may be electrically isolated from the semiconductor layers by one or more insulating layers 103 between the semiconductor layers and the electrode structures. The electrode structures may include a gate structure, e.g., a plurality of plunger gates 106₁₋₃, in this example connected to a common gate electrode 105. In other embodiments, each gate may be connected to a dedicated electrode, resulting in a more complicated lay-out but a simpler control. By applying a voltage 107 to the gate electrode, quantum dot regions 110₁₋₃, e.g., quantum wells, may be formed under the plunger gate in the one or more semiconductor layers in which charge carriers (e.g., electrons and/or holes) are laterally confined. The voltage V_{g} of the gate electrode may be tuned such that a quantum well is formed. The gate voltage may be tuned such that exactly one charge carrier 112₁₋₃ (e.g. an electron or a hole) is confined in each quantum well. This voltage will typically determine the working voltage of the quantum dots. Thus, the charge carrier is trapped in a potential well which is separated from neighboring potential wells by barrier potentials located between the quantum dot regions. The height of the potential barriers 114_{1,2} may be controlled by barrier electrodes 108₁₋₄ which, in the depicted example, are also connected to a common barrier electrode 111 to control barrier electrodes between the quantum dots. In other embodiments, each gate may be connected to a dedicated electrode, or more complicated configurations may be used. Applying a barrier voltage V_{b} 109 to the barrier gate may control the barrier height 114_{1,2}, e.g., lower the barrier, so that charge carriers configured as qubits may interact with each other.

The electron is a spin-½ particle, and therefore, a single electron in a quantum dot can form a quantum mechanical two-level system (or an approximation thereof), defined by the electron spin-up and spin-down states. The spin of an electron is an intrinsic angular momentum giving rise to a magnetic dipole moment. The magnitude of this dipole moment is given by the Bohr magneton μ_{B}. As a result, an external magnetic field Bₑₓₜ splits the spin-up and spin-down states in energy due to the Zeeman effect. In the example depicted in FIG. 1A, the external magnetic field is created by one or more magnets 1161,2.

The spin states of an electron in a magnetic field may serve as the computational basis states of a qubit in what is referred to as a single-spin qubit. The single-spin qubit is the simplest form of a spin qubit, but several other implementations of spin qubits exist, which employ spin states of more than one electron in more than one quantum dot to define a qubit. In contrast with the single-spin qubit, all other types of spin qubits constitute an effective pseudo-spin two-level system. Examples of other spin qubit implementations are a singlet-triplet qubit (two electrons in two dots), a hybrid qubit (three electrons in two dots), an (always-on) exchange-only qubit (three electrons in three dots), as well as a quadrupolar exchange-only qubit (four electrons in three dots). All these spin-qubit implementations attempt to mitigate certain decoherence mechanisms or to reduce the experimental requirements at the expense of complexity. In general, using spin states as basis states for a qubit has the advantage of long coherence times, compared to for example a charge qubit, because spin does not interact directly with electric noise. However, spin-orbit coupling does provide an indirect coupling, which still causes decoherence, albeit less than for charge qubits. With a reduced effect of electrical noise sources, the hyperfine interaction is also a relevant decoherence mechanism for spin qubits.

Spin-orbit coupling results in eigenstates that are admixtures of spin and orbital states. Electric noise does not couple directly to spin, but it does couple to the orbital part of the quantum state, leading to spin relaxation. The most important source of electric noise in experimental setups with proper filtering is formed by acoustic phonons. Hyperfine interaction is an interaction between the spin of an electron in a quantum dot with the spin of nuclei in the host material. This results in a random evolution of the electron spin, causing decoherence.

Single-qubit gates for single-spin qubits are based on the interaction of spin with magnetic fields. The Zeeman effect lifts the degeneracy of spin states in a magnetic field. Additionally, an oscillating magnetic field B₁ perpendicular to the static field that splits the spin-up and spin-down states, drives so-called Rabi transitions between these states if the oscillation frequency f matches the energy difference (h f=g μ_{B} Bₑₓₜ, where h is Planck's constant and g is the electron g-factor; g=2 in silicon). This is called electron spin resonance (ESR) and its most direct implementation is by applying an oscillating magnetic field by passing an alternating current with frequency f through an on-chip microwave stripline close to the electron spin. This has been demonstrated both in GaAs and silicon devices. Careful stripline design results in bulky structures, making it challenging to properly implement several striplines in one device and to achieve individual addressability of several electron spins. Furthermore, dissipation in the stripline causes sample heating, but this can be circumvented by using a superconducting material for the stripline. Therefore, it is advantageous to address the qubits without the use of microwave striplines.

Alternatively, an electron can also be made to experience an effective oscillating magnetic field by moving it back and forth in a spatially varying magnetic field (i.e., a magnetic field with a non-zero magnetic field gradient), thereby driving spin transitions if the frequency of the oscillating motion matches the energy difference between the spin-up and spin-down states. In that case the coupling is indirect, via the charge of the electron, and the effect is referred to as electric dipole spin resonance (EDSR). A magnetic field varying on the length scale of quantum dots can be generated by micron sized magnets in the proximity of the dots, as depicted in FIG. 1B-E.

Spin-orbit coupling (SOC) can also give rise to an effective magnetic field experienced by a moving electron, and for that reason the magnetic field gradient generated by micromagnets is sometimes called an artificial spin-orbit field. In GaAs, spin-orbit coupling can be used as an efficient driving mechanism, but in bulk silicon spin-orbit coupling is weak and spin-orbit driving inefficient.

Thus, the charge carriers 112₁₋₃ (acting as qubits) in the quantum dot regions 110₁₋₃ in FIG. 1A may be controlled through Electric Dipole Spin Resonance (EDSR). In particular, FIG. 1A schematically depicts a plurality of qubits created by introducing a large magnetic field Bₑₓₜ, using one or more magnets 116_{1,2}, that splits the energy of the electron spin (Zeeman-split). The qubit states (e.g., spin-up and spin-down, typically denoted as |0> and |1>> are the states where the electron spin aligns and anti-aligns with this magnetic field Bₑₓₜ that quantizes the energy state. The magnetic field in the direction of the ‘quantization’ axis is known as the longitudinal magnetic field Bᵢₗ. In the examples depicted in this disclosure, the longitudinal magnetic field is chosen in the x-direction, i.e., Bᵢₗ=Bₓ, but other choices are equally valid.

In a typical configuration, the magnetic field in the quantum dot regions is dominated by the longitudinal magnetic field, i.e., Bᵢₗ>>B_{⊥}, where B_{⊥} denotes a transverse magnetic field component. For example, if the longitudinal field is chosen in the x-direction, the transversal field may be chosen in the y- and/or z-directions. The gradient of this transversal field may be defined (predominantly) in, e.g., the x, y, or z direction. The direction of the transversal field and the transversal field gradient may be different for different quantum dot regions.

The magnitude of the total magnetic field determines the Zeeman energy-splitting and, hence, the resonant frequency f_{q} of the qubit. By introducing a gradient in the transverse magnetic field component B_{⊥}, the qubit can be controlled through EDSR.

As was mentioned above, EDSR control works through oscillating the electron at its resonance frequency through an electrical interaction in the direction of the transversal field gradient by applying voltages on one or more nearby electrodes. The transverse electric field may be chosen, for example, in the y-direction, i.e., B_{⊥}=B_{y}. Then, if dB_{y}/dx>0 and dB_{y}/dy=0, the electron may be oscillated in resonance along the x-direction, and if dB_{y}/dy>0 and dB_{y}/dx=0, the electron may be oscillated in resonance along the y-direction. This leads to an effective magnetic field perpendicular to the quantization axis (in this example, the x-axis), around which the electron spin can precess. This allows for the application of quantum gates.

In summary, an EDSR controlled qubit requires a longitudinal magnetic field (e.g., Bₓ), a transverse magnetic field gradient (e.g., dB_{y}/dx), and an oscillating electric field along the direction of the transverse magnetic field gradient to electrically oscillate the electron. The same arguments and requirements apply for other charge carriers, e.g., when a hole is used instead of an electron. The transverse magnetic field gradient can be created by one or multiple micromagnets close to the qubits, as seen in FIG. 1B-D.

These micromagnets can serve a dual use, which may be optimized independently, up to a point. In addition to generating the transverse magnetic field gradient, they can also facilitate selective qubit control, i.e., create individually addressable qubits by changing the properties (e.g., the size) of the micromagnets. If one would like to control one out of many qubits in a system, like in FIG. 1B, one either needs to electrically oscillate this qubit alone, requiring a very focused electrical field, or make sure that the oscillation is at the frequency of only the particular qubit to be controlled. Since it is preferable to have the qubits close to each other for them to interact, it is difficult to selectively oscillate a particular qubit without oscillating its neighbors (‘cross-talk’): if the magnetic field strength is the same, so is the Zeeman-split, and hence the resonance frequency.

In order to make the qubits individually addressable, measures may be taken to ensure that the qubits have unique resonant frequencies. This can be done with one or more micromagnets placed in close proximity to the qubits. FIG. 18 shows the same quantum dot structure as FIG. 1A, with the addition of a plurality of micromagnets 120₁₋₄ arranged symmetrically around the quantum dot regions 110₁₋₃. For clarity, the electrodes for controlling the gates are not shown. This is a configuration as proposed in some designs for quantum dot arrays; however, actual implementation and fabrication of such designs has so far not been published. The local magnetic fields for a single quantum dot are schematically depicted in FIGS. 1C and 1D.

FIG. 1C depicts a top view and FIG. 1D depicts a side view of a single pair of micromagnets positioned on opposite sides of a single qubit. The magnetic field is schematically indicated using field lines. A magnetic field in general has components in all three spatial directions as well as gradients of each component in all three directions, so in total there are twelve relevant quantities to consider in designing micromagnets for EDSR driving of spin qubits. However, Maxwell's equations and symmetry reduce the number of independent quantities.

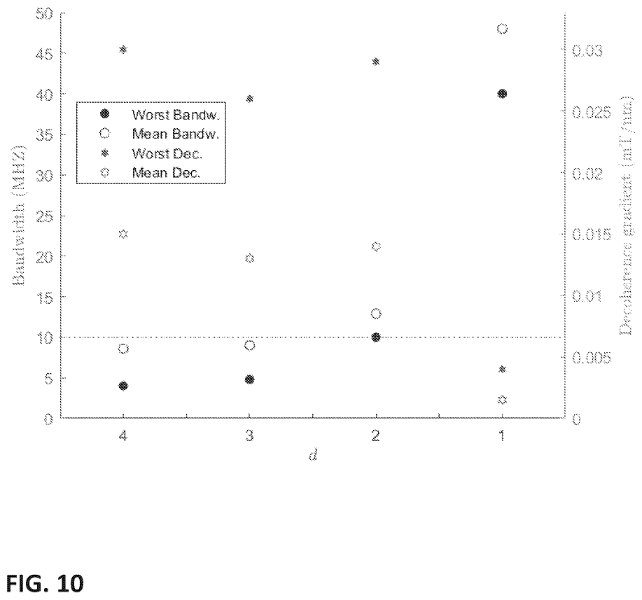

The coordinate frame used in these examples is shown in FIGS. 10-E. The 2DEG is formed in the x-y plane. An in-plane external magnetic field is applied along the x-direction, so the x-component of the magnetic field generated by the micromagnet(s) is parallel to the external magnetic field: Bₗₗ=Bₓ. The y and z components of the micromagnet field add up to form the perpendicular magnetic field. The qubit frequency is defined by the absolute value of the total magnetic field via the Zeeman splitting. As the magnetic field is typically dominated by the externally applied longitudinal field (Bₗₗ>>B_{⊥}), the Zeeman splitting is approximately proportional to the longitudinal magnetic field component.

For a magnet design with reflection symmetry in the y-z plane (indicated in FIG. 1C,D with dash-dotted lines), B_{y} and B_{z} vanish in this plane. Since the qubit region 110₁ is on this plane, B_{y} and B_{z} vanish at the center of the qubit region, and Bₓ is the only relevant component. This is also typically the case for proposed micromagnets configurations for two-dimensional quantum dot arrays; however, the applicant has found that since the transversal magnetic field is typically much smaller than the longitudinal magnetic field, non-reflection-symmetric configurations may be used for the transverse field without introducing unacceptable noise levels. Thus, the qubit addressability is determined by the difference in field strength between (neighboring) quantum dots of the longitudinal (or parallel) magnetic field component. In typical prior art configurations, this difference naturally gives rise to an in-field gradient of the longitudinal magnetic field, given by a, ∂_{xy}Bₗₗ=\sqrt{(∂ₓBₓ)²+(∂_{y}Bₓ)²}. This gradient, however, also causes decoherence and therefore should be minimized given the required minimal addressability. Consequently, a balance must be found between addressability and decoherence.

The qubits are assumed to be driven in the x-direction, so the gradient responsible for driving of the electron spin is given by: dB_{⊥}/dx. Here, the quantization axis is assumed to be fixed in the x-direction, which to first-order is correct, since B_{y} and B_{z} are negligible compared to Bx (and may even vanish at the positions of the qubits). All other gradients purely cause decoherence and should be minimized. In the current example, the main contribution to the driving gradient is dB_{z}/dx, which therefore should be maximized. Simultaneously also the decohering gradient dBₓ/dz will be maximized, but that cannot be prevented; however, as in a 2DEG or 2DHG the charge carriers are essentially confined to a plane at constant z, the dBₓ/dz gradient in practice has a very limited effect.

FIG. 1E shows a configuration with a plurality of qubit regions 110₁₋₃ in between a pair of different micromagnets 122_{1,2}. Thus, the micromagnets can be configured to make the magnetic field at the location of each spin-qubit unique. This, however, leads to a gradient in the longitudinal field, as seen in the schematic plot of Bₓ(x) in FIG. 1E. And this, in turn, leads to noise in the qubit, since its resonant frequency readily changes due to noise in the environment. Note that for EDSR, a transverse gradient is required, which can be generated in the same manner as described before. The transverse magnetic field gradient may be equal for all qubit regions or may be different for different qubit regions. The spin-qubit then should be oscillated along this transverse field gradient at its own resonant frequency dictated by the longitudinal field Bx, to execute the qubit rotation.

In summary, in the design of scalable quantum dot chips, several conflicting requirements must be met. For example, the quantum dots should be positioned as close together as possible, in order to improve the efficiency of the chip and the quantum dot interaction. Furthermore, quantum dots are typically addressed by using radiation tuned to the Zeeman split of the energy levels of the electron in the quantum dot. As the Zeeman split is proportional the magnitude of the magnetic field, so is the resonance frequency. Therefore, it is desirable to maximize the difference of the magnitude of the magnetic field between neighboring quantum dots. This reduces cross-talk between neighboring dots and improves operation speed. On the other hand, the spatial derivatives (gradient) of the magnetic longitudinal field strength in the quantum dot plane should be minimized, in order to reduce noise. This noise is at least in part due to the electrons moving around in the quantum dot regions. The lower the gradient of the magnetic field, the less the effective broadening of the quantum dots frequency and the less the quantum dots decohere. Evidently, the requirement of maximally different magnetic field strengths at close distances is in conflict with the requirement of minimal spatial derivatives of the magnetic field strength. The gradient of the longitudinal magnetic field (i.e., the quantization field) is sometimes referred to as the decoherence gradient.

It has been found that the noise is minimized if the magnetic field strength is maximally symmetric around the quantum dot region.

In practice, the magnetic field strength is dominated by a single component. In the examples shown in the Figures, this is assumed to be the x-component, i.e., |Bₓ|≈[\vec{B}], where \vec{B} denotes the (vector-valued) magnetic field, Bₓ denotes the x-component of the magnetic field, and |·| denotes the standard norm. However, it should be noted that in principle, the magnetic field can have any configuration. Furthermore, in typical configurations, a distinction can be made between a macroscopic magnetic field defined by a relatively large (compared to the array of quantum dots) magnet, and a microscopic magnetic field comprising local changes to the macroscopic magnetic field created by micromagnets placed close to quantum dots. These micromagnets may have lateral dimensions of the same order of magnitude as the distance between neighboring quantum dots, e.g., about 10-100 nm. Micromagnets smaller than 1 μm may also be referred to as nanomagnets. The micromagnets are typically paramagnets which are magnetized by the macroscopic magnetic field.

In currently studied quantum chips, the quantum dot regions are typically constrained to a plane whose lateral dimensions (x and y) are typically orders of magnitudes larger than its vertical dimension z. As a consequence, the z-component of the gradient (e.g., ∂_{z}Bₓ) can typically be ignored. Therefore, unless otherwise noted, whenever a gradient is mentioned, only the in-plane gradient (∂ₓ, ∂_{y}) is considered. For notational convenience, the norm of the in-plane gradient of a function B is written as ∂_{xy}B, i.e.,

$${\partial }_{xy} B := \sqrt{{( {\partial }_{x} B )}^{2} + {( {\partial }_{y} B )}^{2}}$$

It is an aim of embodiments in this disclosure to maximize the difference in magnetic field strength or longitudinal magnetic field component between neighboring quantum dots while minimising the gradient of the magnetic field or magnetic field component in the quantum dot regions in the plane defined by the quantum dot regions.

In the following examples, the difference between the magnitude of the x-component of the magnetic field between neighboring quantum dots is maximized while minimizing the in-plane gradient of the x-component of the magnetic field. For example, for each quantum dot i, the smallest difference with each neighbor, i.e., minⱼ(|Bₓ(pᵢ)−Bₓ(pⱼ)|); may be maximized, where pᵢ and pⱼ denote the positions of neighboring quantum dots, while (∂ₓBₓ(pᵢ))²+(∂_{y}Bₓ(pᵢ)²=(∂_{xy}Bₓ(pᵢ))² is minimized. Alternatively, the sum Σⱼ|Bₓ(pᵢ)−Bₓ(pⱼ)| could be maximized; this may on average lead to a larger difference, but may result in a smaller (and hence, worse) smallest difference. Depending on the details of the quantum dot structure and the envisioned use, different metrics may be envisaged.

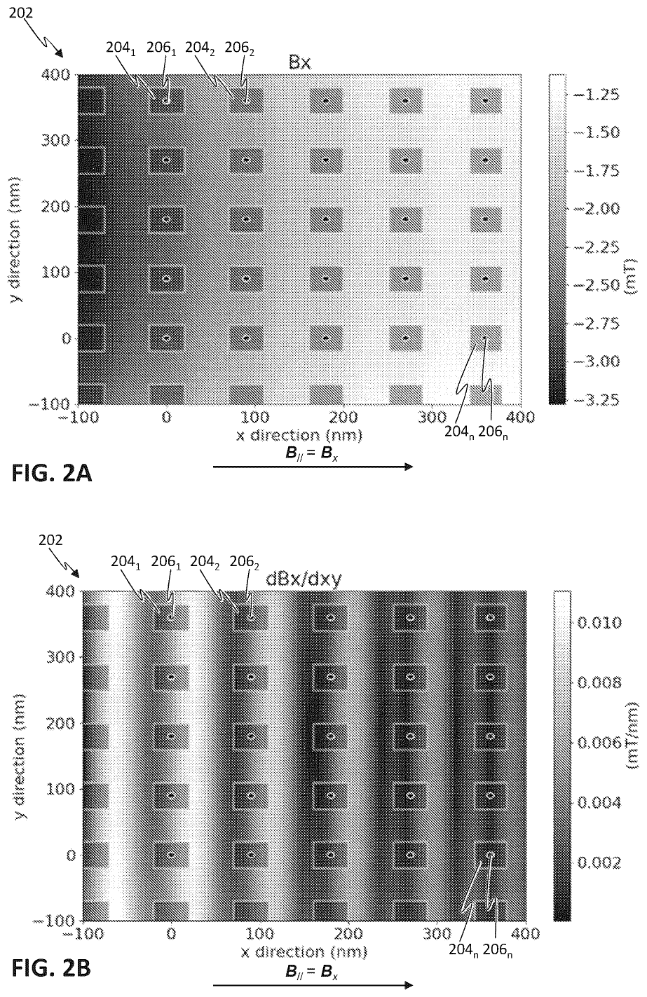

FIGS. 2A and 2B schematically depict a prior-art micromagnet configuration. For the sake of comparison, FIGS. 2A and 2B depict, respectively, the magnetic field strength Bₓ and the magnetic field gradient ∂_{xy}Bₓ for a prior-art micromagnet configuration in a square 2-dimensional array 202 with a 90 nm spacing between quantum dots. In the depicted configuration, a micromagnet 204₁₋ₙ is placed over each quantum dot 206₁₋ₙ (as has been proposed in some prior-art documents). Furthermore, a large-scale external field (Bₑₓₜ=Bₗₗ=Bₓ) is present that slowly decays with increasing x.

Intuitively, in this configuration, since the micromagnets are positioned fully symmetric with regards to each quantum dot, the magnetic field strength Bₓ will also be (at least approximately) the same for each quantum dot. The same is true for other configurations that are reflection-symmetric along the axes defined by the grid lay-out, for example, a configuration where the micromagnets are shifted half the distance between two quantum dots in the x-direction (another commonly proposed configuration). This can also be seen in FIG. 2A, and is confirmed by simulations (simulating a 10×10 micromagnet array over a 10×10 quantum dot array). Indeed, in the depicted configuration, the mean difference in Bx is 0.054 mT and the worst (lowest) difference is 0.023 mT. As was mentioned before, based on current technology, a minimum difference of about 0.35 mT may be required for the qubits to be individually addressable. In other words, prior-art configurations underperform by about an order of magnitude. (Simulation parameters are provided below in the description of FIG. 10.)

A reason this configuration (and similar ones) have been proposed, is that they locally optimize (minimize) the magnetic field gradient, thus reducing noise. This can be seen in FIG. 2B, and is confirmed by simulations, showing that the mean ∂_{xy}Bₓ is 0.0034 mT/nm and the worst (highest) is 0.0066 mT/nm, which is well below the value of 0.1 mT/nm that is generally deemed acceptable.

As the size of the array increases, both the magnetic field strength and the field gradient decrease, as the symmetry of the system increases. Consequently, scaling up the system reduces the individual addressability.

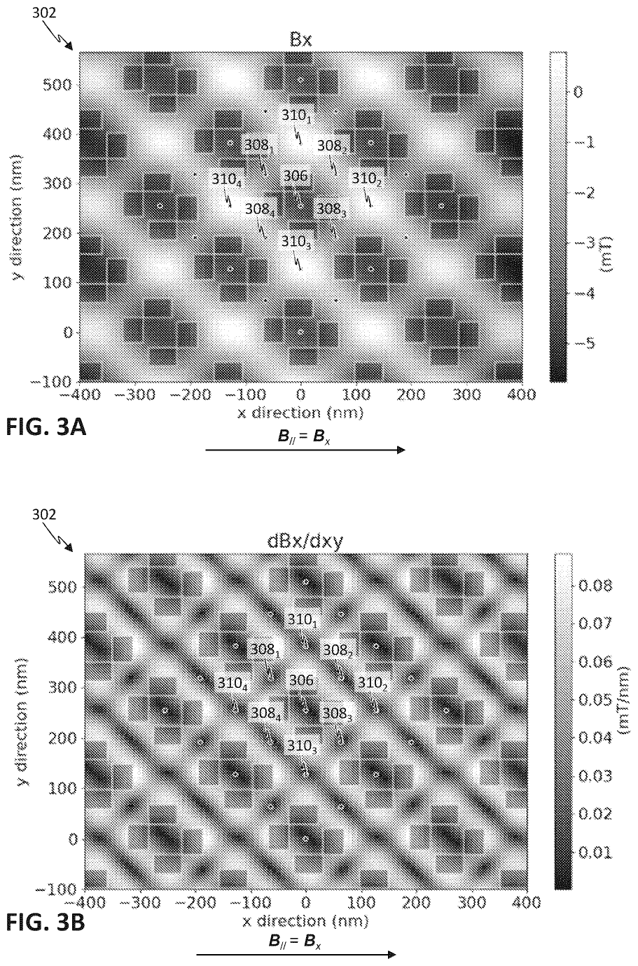

FIGS. 3A and 3B schematically depict a micromagnet configuration according to an embodiment. FIGS. 3A and 3B depict, respectively, the magnetic field strength B, and the magnetic field gradient ∂_{xy}Bₓ for a pmm-group-based micromagnet configuration in a square 2-dimensional array 302 with a 90 nm spacing between quantum dots. The quantum dot array is identical to the array shown in FIG. 1A, but has been rotated over 45° in order to simplify the numerical simulations. In this example, identical, rectangular (non-square) micromagnets are used. The configuration is rotationally symmetric over 180° around each quantum dot, and is moreover reflection-symmetric around the array axes (the diagonal axes, as depicted). In the depicted configuration, the mean difference in Bₓ is 1.7 mT and the worst (lowest) difference is 1.35 mT, well above the 0.35 mT threshold. These values are about 30 (mean) to 60 (worst) times better than the prior-art configuration shown in FIG. 2A.

In this example, quantum dot 306 is located at a local minimum of the longitudinal magnetic field, quantum dots 308_{1,3} are located at a first saddle point of the longitudinal magnetic field, quantum dots 308_{2,4} are located at a second saddle point of the longitudinal magnetic field, and quantum dots 310₁₋₄ are located a local maximum of the longitudinal magnetic field.

In the limit of an infinitely large micromagnet array and absent any external magnetic field gradient, there are four different field strengths. In the depicted example, due to finite-size effects and limits to numerical precision, there can be small variations between similarly positioned quantum dots. For example, quantum dot 306 has Bₓ=−4.66±0.04 mT, quantum dots 308_{1,3} have Bₓ=−2.49±0.03 mT, quantum dots 308_{2,4} have Bₓ=−0.70±0.02 mT, and quantum dots 310₁₋₄ have Bₓ=0.54±0.09 mT.

FIG. 3B shows that, because of the symmetries, each quantum dot is located in a local minimum of the field gradient. The simulated field gradient is 0.0014 mT/nm (mean) and 0.0038 mT/nm (worst), which is an improvement compared to the configuration shown in FIG. 2B, and also well below the acceptability threshold.

It has been shown that is not possible to create a 2D pattern in which the field Bₓ is different between (direct and diagonal) neighboring dots while the gradient ∂_{xy}Bₓ is zero in those dots, except when the micromagnets are configured based on a p2 or pmm wallpaper group; at least, if no assumptions are made with regards to direction of the magnetic field. Since the configurations based on the p2 and pmm wallpaper group have the advantages described above regardless of the direction of the magnetization. This provides increased protection against misalignment, disturbances and general deviations from the magnetic field as well as additional design freedom.

In an embodiment, an additional magnetic field parameter is optimized (for instance, the transverse magnetic field gradient, e.g., dB_{y}/dx). A way to incorporate the additional magnetic field is e.g. by adding a bigger micromagnet next to the array of dots which creates this transverse magnetic field gradient.

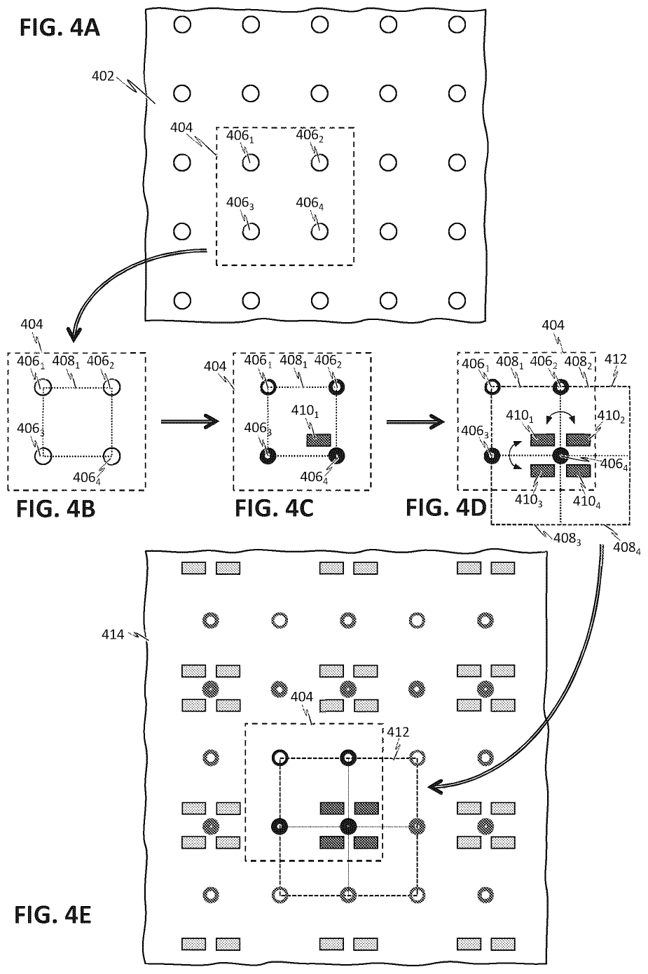

FIG. 4A-E schematically depict application of a pmm-wallpaper-group based micromagnet configuration to a quantum dot array according to an embodiment. FIG. 4A depicts a (segment of a) rectangular, in particular a square quantum dot array 402. The shown segment comprises 5×5 quantum dots, indicated with circles. In the absence of any micromagnets, all quantum dots are equal. In the following steps, a tile 404 comprising four quantum dots 406₁₋₄ is considered in more detail. The full quantum dot array can be obtained by tiling a plane with the tile 404. In this application, quantum dot 406₂ may be referred to as a horizontal neighbor of quantum dot 406₁, quantum dot 406₃ may be referred to as a vertical neighbor of quantum dot 406₁, and quantum dot 406₄ may be referred to as a diagonal neighbor of quantum dot 406₁. Thus, each quantum dot has eight neighbors, which can be divided into two horizontal neighbors, two vertical neighbors, and four diagonal neighbors.

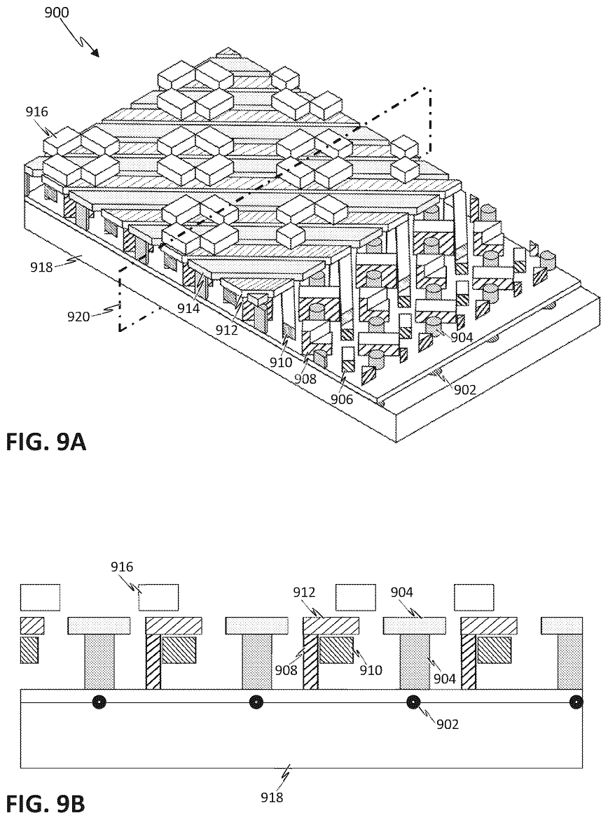

FIG. 4B shows the tile 404. The four quantum dots 406₁₋₄ define a rectangle, in particular a square 408₁. FIG. 4C show the effect of adding a micromagnet 410₁ inside the square 408₁. The micromagnet is positioned such that the magnetic field created by the micromagnet is different for each of the four quantum dots 406₁₋₄. For example, assuming a homogeneous micromagnet, the micromagnet may be positioned such that it is furthest from a first quantum dot 406₁, second furthest from (or third closest to) a second quantum dot 406₂, second closest to (or third furthest from) a third quantum dot 406₃, and closest to a fourth quantum dot 406₄. Additionally or alternatively, a varying magnetic field strength can be achieved by using a micromagnet containing different materials in an inhomogeeous distribution, varying the thickness of the micromagnet, et cetera. The micromagnet may touch one or more borders of the rectangle 408₁. Typically, the micromagnet is fabricated in one or more layers of a quantum chip different from the layer containing the quantum dots, e.g., in a layer above and/or below the quantum dots. A difference in magnetic field strength can be obtained by varying a distance in the out-of-plane direction between the micromagnet and the quantum dots. A plurality of micromagnets may be placed in the rectangle 408₁. The placement of the micromagnets can be affected by other considerations, such as, e.g., the placement of electrodes used to control the quantum dots. This will be discussed in more detail below with reference to FIG. 9A,B.

FIG. 4D depict the generation of a tile 412 having the symmetries of the pmm wallpaper group, based on the rectangle 408₁. The rectangle 408₁ is reflected in a vertical axis coinciding with a vertical edge of the rectangle, resulting in a rectangle 408₂. Subsequently both rectangles are reflected in a horizontal axis coinciding with a horizontal edge of the rectangles, resulting in rectangles 408₃ and 408₄. Rectangle 408₄ can also be obtained by rotating rectangle 408₁ over 180° around one of its corners.

It should be noted that the symmetries relate to the material structure and, hence, to the magnitude of the magnetic field, but not necessarily to the direction of the magnetic field. The micromagnets are typically paramagnets magnetized by an external magnetic field. Therefore, if, for example, micromagnet 410₁ has its North pole on the right hand side and its South pole on the left hand side, than the “mirrored” micromagnet 410₂ still has its North pole on the right hand side and its South pole on the left hand side. It should also be noted that when micromagnet 410₁ touches an edge of rectangle 408₁, it becomes, in practice, a single structure with the “mirrored” micromagnets touching the same edge.

The resulting tile 412 is rotationally symmetric over 180° around its center—coinciding with quantum dot 406₄—and reflection-symmetic over its central axes—coinciding with the axes through vertically neighboring quantum dots 406₂ and 406₄, and though horizontally neighboring quantum dots 406₃ and 406₄, respectively. By extending the tessellation based on tile 412, a configuration is obtained that is rotationally symmetric over 180° around each quantum dot, and reflection symmetric over all axes through horizontally or vertically neighboring quantum dots. In this example, quantum dot 406₄ is located at a local maximum of the magnetic field, quantum dot 406₃ is located at a first saddle point of the magnetic field quantum dot 406₂ is located at a second saddle point of the magnetic field, and quantum dot 406₁ is located at a local minimum of the magnetic field.

The result is shown in FIG. 4E. The result is a quantum dot array 414 in which the magnetic field strength created by the micromagnets in a qantum dot may have a first value; the magnetic field strength in the horizontal neighbors may have a second value, different from the first value; the magnetic field strength in the vertical neighbors may have a third value, different from the first and second values; and the magnetic field strength in the diagonal neighbors may have a fourth value, different from the first, second, and third values. The rotationally symmetric placement of the micormagnets around each of the quantum dots moreover ensures that the in-plane derivative of the magnetic field strength generated by the micormagnets in the quantum dots is zero, or at least tends to zero as the array becomes infinitely large.

In some embodiments, the quantum dot array may comprise one or more quantum dots that need not to be addressable. For the purpose of the designs described in this disclosure, such quantum dots may be ignored; or in other words, they may be placed wherever that is convenient, as they do not, or not significantly, affect the magnetic field in the addressable quantum dots.

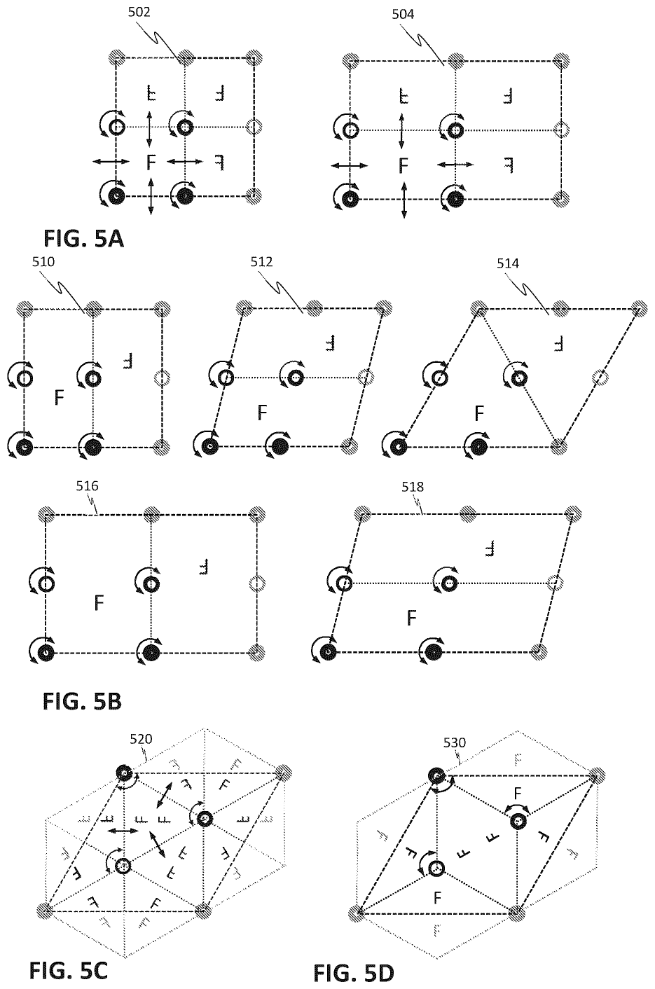

FIG. 5A-D schematically depict various wallpaper groups. It is well-known that there are 17 distinct symmetry groups describing repetitive patterns of a two-dimensional plane; these are known as the wallpaper groups. Each wallpaper group can be represented by one to eight fundamental domains, which together form a primitive cell (a tile). The fundamental domain is the smallest repeating element. The fundamental domains can be mapped onto each other by rotation and/or reflection. The fundamental domains do not have any internal symmetries. In the images in FIG. 5A-D, each fundamental domain is indicated with one or two symbols “F”. In the example shown in FIG. 4D, the fundamental domains are rectangles (in this case, squares) 408₁₋₄, which together form primitive cell 412. When determining a micromagnet design based on a wallpaper group, each fundamental domain should comprise (a part of) a micromagnet. The micromagnet configuration in the other fundamental domains can be obtained by reflection and/or rotating a first fundamental domain.

Each wallpaper group has zero to four distinct rotational symmetry centers. The requirement that the in-plane derivative of the magnetic field strength vanishes translates to the requirement that the quantum dots be positioned at a rotational symmetry centers of the micromagnet configuration with an even rotational symmetry (e.g., 2-fold over 180°, 4-fold over 90°, or 6-old over) 60°. In this application, two rotational symmetry centers are considered distinct if they have different magnetic field strengths. The difference in magnetic field strength results from the requirement that the fundamental domains do not have internal symmetries. There are two wallpaper groups with four distinct rotational symmetry centers: the pmm wallpaper group and the p2 wallpaper group.

Thus, in general, embodiments may relate to micromagnet configurations for a quantum dot array based on a wallpaper symmetry group having at least two distinct rotational symmetry centers, wherein each individually addressable quantum dot is positioned in a rotational symmetry center, and wherein a non-symmetric micromagnet configuration defines a fundamental domain.

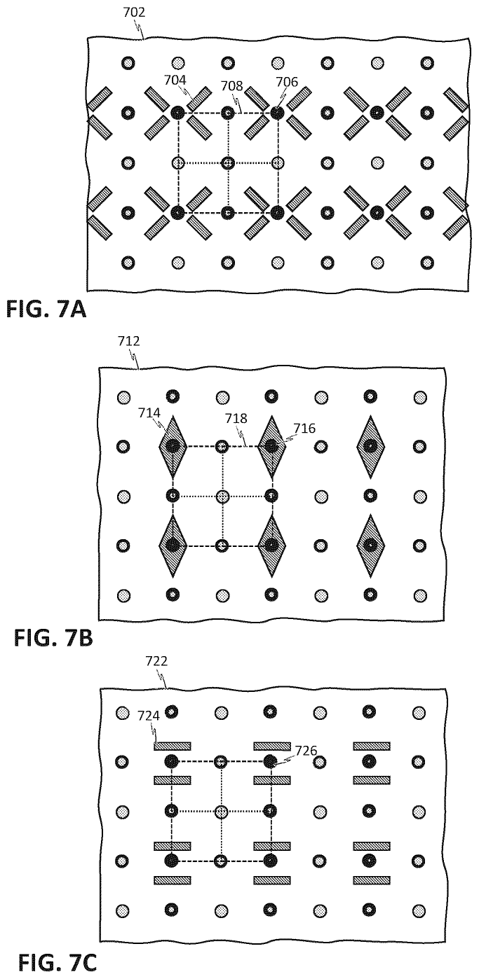

FIG. 5A depict the symmetries of the pmm wallpaper group. This is the wallpaper group with the largest number of symmetries while also having four distinct rotational symmetry centers, each having a 180° rotational symmetry. The pmm wallpaper group has a rectangular, possibly square primitive cell comprising four rectangular, possibly square fundamental domains. Configuration 502 depicts the square configuration, while configuration 504 depicts a non-square rectangular configuration. This configuration has been described in some detail with reference to FIG. 4A-E above. Further examples are shown in FIG. 3A,B and FIG. 7A-C.

FIG. 5B depict the symmetries of the p2 wallpaper group. This wallpaper group has the same rotational symmetries as the pmm wallpaper group, but lacks the reflection symmetries. As a result, this configuration has the same individual addressability as the pmm-based configuration, but is more susceptible to noise. It is, however, an advantage that the fundamental domain is twice as large (assuming the same distance between the quantum dots) as in the pmm case, which may simplify manufacturing.

A further advantage of the p2 wallpaper group is that it can be applied to a wider range of quantum dot arrays. The pmm wallpaper group can only be used with rectangular quantum dot arrays; the p2 group can be applied to any parallelogram-based array. In particular, configuration 510 depicts a square configuration, similar to configuration 502, and configuration 516 depicts a rectangular configuration, similar to configuration 516. Configuration 518 depicts a generic parallelogrammatic (or oblique) configuration. Configuration 512 depicts a generic rhombic configuration. Configuration 514 depicts a so-called hexagonal configuration.

It should be noted that the shown division into fundamental domains is arbitrary; any line passing through the center results in an equivalent configuration; the choice to depict the dividing line through centers of opposite edges or opposite corners is one of convenience.

FIG. 5C depict the symmetries of the p3m1 wallpaper group. The p3m1 wallpaper group has three distinct rotational symmetry centers, each having a 120° rotational symmetry (i.e., three-fold rotational symmetry). The three distinct rotational symmetry centers form the corners of a regular triangular fundamental domain. A primitive cell having the shape of a regular hexahedron can be obtained by reflection of the fundamental domain over one of its edges and rotating the fundamental domain and its reflection together over +120° and −120° around a vertex on the reflection axis. The p3m1 wallpaper group has a single, hexagonal configuration 520.

Compared to the p2 wallpaper group, and advantage of the p3m1 wallpaper group is its higher degree of symmetry; whereas the p2 wallpaper group has the advantage that it has one more distinct rotational symmetry center.

FIG. 5D depict the symmetries of the p3 wallpaper group. The p3 wallpaper group has the same three distinct rotational symmetry centers as the p3m1 wallpaper group, and similarly has only a single, hexagonal configuration 530. Compared to the p3m1 wallpaper group, the p3 wallpaper group lacks the reflection symmetries.

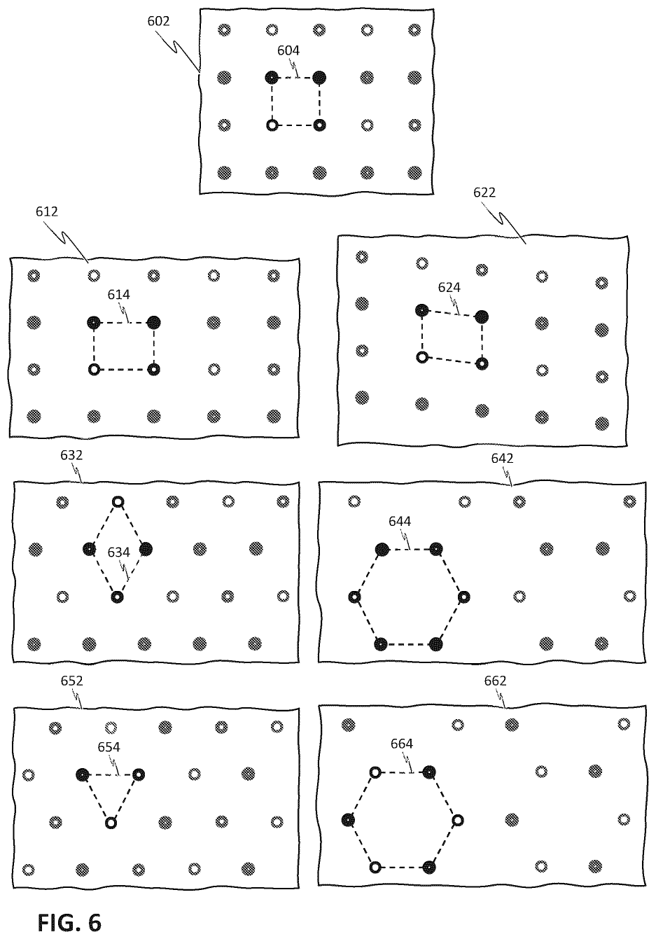

FIG. 6A schematically depict quantum dot arrays according to various embodiments. Quantum dot array 602 is a square quantum dot array. If a micromagnet configuration based on the ppm or p2 wallpaper group is used, four distinct quantum dots are created, which form a square 604. Each quantum dot has two distinct direct (horizontal and vertical) neighbors, and four identical diagonal neighbors which are distinct from the direct neighbors. The nearest quantum dot with the same magnetic field is positioned 2 dots away.

Quantum dot array 612 is a non-square rectangular quantum dot array. If a micromagnet configuration based on the ppm or p2 wallpaper group is used, four distinct quantum dots are created, which form a rectangle 614. Each quantum dot has two distinct direct (horizontal and vertical) neighbors, and four identical diagonal neighbors which are distinct from the direct neighbors. The nearest quantum dot with the same magnetic field is positioned 2 dots away, in this example in the vertical direction.

Quantum dot array 622 is a non-square rectangular quantum dot array. If a micromagnet configuration based on the p2 wallpaper group is used, four distinct quantum dots are created, which form a non-rectangular parallelogram 624. Like in the square and rectangular quantum dot arrays, diametrically opposite neighbors of a quantum dot are identical. The nearest quantum dot with the same magnetic field is positioned 2 dots away, but the direction depends on the details of the parallelogram.

Quantum dot array 632 is a quantum dot array that may be considered triangular or rhombic. If a micromagnet configuration based on the p2 wallpaper group is used, four distinct quantum dots are created, which form a rhombic parallelogram 634. The parallelogram can be divided into two equilateral triangles. Each quantum dot has three pairs of distinct neighbors. The nearest quantum dot with the same magnetic field is positioned 2 dots away.

A hexagonal quantum dot array 642 can be created from the triangular quantum dot array 632 by removing the quantum dot at the center of each hexagon. Each quantum dot has three distinct neighbors. The nearest quantum dot with the same magnetic field is positioned on the diametrically opposed corner of the hexagon.

Quantum dot array 652 is a quantum dot array is identical to quantum dot array 632, and may thus similarly considered triangular or rhombic. If a micromagnet configuration based on the p3m1 or p3 wallpaper group is used, three distinct quantum dots are created, which form an equilateral triangle 654. Each quantum dot has two distinct neighbors. Two adjacent equilateral triangles can be combined into a rhombic parallelogram; the nearest quantum dot with the same magnetic field is positioned on the opposite corner of the resulting parallelogram.

A hexagonal quantum dot array 662 can be created from the triangular quantum dot array 652 by removing the quantum dot at the center of each hexagon 664. Each quantum dot has one distinct neighbor. The nearest quantum dot with the same magnetic field is positioned two corners away along the hexagon.

Several of these quantum dots arrays have been proposed in the art, including square, oblique, and hexagonal, but without the micromagnet configurations as described herein.

FIG. 7A-C schematically depict micromagnet configurations according to various embodiments. In these examples, the micromagnet configuration is based on the ppm wallpaper group. FIG. 7A depicts a micromagnet configuration 702 similar to the one shown in FIG. 3A. The primary cell 708 comprises four fundamental domains, each of which comprises a micromagnet 704 positioned roughly diagonally (relative to the quantum dot array), much closer to one of the quantum dots 706 than to the other three quantum dots (at least partially) in the fundamental domain.

FIG. 7B depicts a micromagnet configuration 712 in which a triangular (part of a) micromagnet 714 touches two edges of a fundamental domain of primary cell 718. The result is a non-square rhombic micromagnet covering one of the quantum dots 716.

FIG. 7C depicts a micromagnet configuration 722 similar to the one shown in FIG. 4E. However, in this example, the micromagnet 724 touches one of the edges of a fundamental domain of primary cell 728. The micromagnet is, again, positioned much closer to one of the quantum dots 706 than to the other three quantum dots touching (or being at least partially in) the fundamental domain.

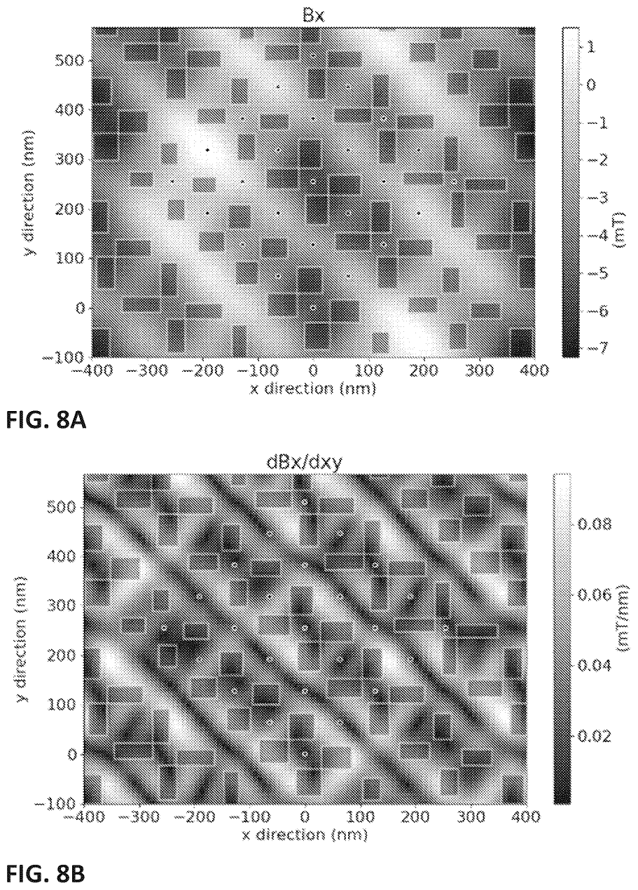

FIGS. 8A and 8B schematically depict a micromagnet configuration according to an embodiment. In this embodiment, not only nearest neighbors are individually addressable, but neighbors up to 5 quantum dots away (in the depicted configuration, about 450 nm). This can be achieved by partly breaking the symmetry of the micromagnet configuration. In this example, this is achieved my modifying the lengths and width of the micromagnets of the configuration shown in FIG. 3A. As a result, the field strength difference will decline and the gradient will increase, compared to the fully symmetric case depicted in FIG. 3A.

In the depicted configuration, the mean difference between (directly and diagonally) neighboring pairs in Bₓ is 0.80 mT and the worst (lowest) difference is 0.14 mT. While the mean is still well above the 0.35 mT threshold, some pairs (about 7% in this example) have a field strength difference of less than 0.35 mT. Still, even the worst difference is almost 3 times larger than the mean difference in the prior-art configuration shown in FIG. 2A.

As can be seen in FIG. 8B, the magnetic field gradient is larger than that of the configuration depicted in FIG. 3B, but still acceptable. The simulated field gradient is 0.016 mT/nm (mean) and 0.040 mT/nm (worst), which is below 0.1 mT/nm. (Simulation parameters are provided below in the description of FIG. 10.) As is discussed in more detail below with reference to FIG. 10, if the cross-talk between quantum dots has a shorter range, the departure from an ‘unbroken’ pmm (or p2) wallpaper group can be smaller, leading to a higher bandwidth. The effect on the decoherence gradient appears to depend less strongly on the minimum distance between quantum dots with the same magnetic field strength.

FIGS. 9A and 9B schematically depict a 3D configuration and a cross-section, respectively, of a chip according to an embodiment. In particular, FIG. 9A schematically depicts a part of a 3D representation of a quantum dot structure 900. The structure comprises a stack of one or more semiconductor layers 918, in which a plurality of quantum dot regions 902 can be formed using plunger gates 904 and barrier gates 906,908. These gates can be controlled using electrodes 914,910,912, respectively. Micromagnets 916 are arranged on top of the electrodes, possibly separated by an insulating layer (not shown). That way, the micromagnets do not interfere with the design for the gates and electrodes, and consequently, the micromagnet configuration may be combined with most or all quantum dot structure layouts.

FIG. 9B shows a cross-section through the same quantum dot structure 900 along the plane 920 marked in FIG. 9A, depicting many of the same structural elements.

In other embodiments, the micromagnets may be positioned, alternatively or additionally, in a different layer, e.g., below the one or more semiconductor layers 918. The micromagnets can also be integrated, partially or completely, in some or all of the barrier gates 906,908 and/or in other structural elements. The size of the micromagnets can vary based on the design. For example, the micromagnets can have, e.g., a width between about 30-60 nm, a length between about 30-100 nm, and a thickness (height) between 10-50 nm.

FIG. 10 depicts simulated measurements on a quantum chip according to an embodiment. In this example, a square quantum dot array was simulated, and the micromagnet configuration was based on the pmm wallpaper group. The parameter d indicates how may direct neighbors in one direction should have a different magnetic field. For d=1, a configuration similar to the one shown in FIGS. 3A and 3B was used (an exact or ‘unbroken’ pmm wallpaper group); whereas for d>1, a configuration similar to the one shown in FIGS. 8A and 8B was used (a ‘broken’ pmm wallpaper group).

The height of the micromagnets was taken to be 30 nm, and the distance between the plane defined by the quantum dots and the plane comprising the micromagnets was taken to be 80 nm. These are currently realistic values that also have been used in previous micromagnet designs. The micromagnets were assumed to be made of fully magnetized cobalt. The distance between the quantum dots was taken to be 90 nm, similarly based on current quantum chip designs. Varying these figures will affect the performance of the micromagnet configuration.

As was already mentioned with reference to FIGS. 3A and 3B, the ‘unbroken’ pmm wallpaper group has a bandwidth that is well above the 10 MHz goal, and a decoherence gradient that is well below the threshold of about 0.1 mT/nm. When the pmm wallpaper group is broken such that the first quantum dot with the same magnetic field strength is three quantum dots away (d=2), the configuration still meets the design goals. For larger values (d>2), the performance slowly decreases. Especially the worst pairs do not quite meet the stated design goals with the used simulation parameters, but they are still reasonably close, such that further optimisation of the configuration may increase the bandwidth to the desired level. Moreover, improvement of the hardware resulting in lower bandwidth requirements, may make the current configurations acceptable. At any rate, the current configuration outperforms the prior art configurations using a regular micromagnet configuration.

From these, the pmm-based configuration shown in FIGS. 3A and 3B easily beats the minimum mark for the bandwidth, while keeping the gradient well below the desired value. The design shown in FIGS. 8A and 8B also is close to a 10 MHz bandwidth, at least for their mean-value; however, a further increase in bandwidth, especially for the currently worst quantum dot pair (e.g., by changing the height of the magnet or distance to the plane comprising the charge carriers), may result to an increase in decoherence gradient which may be undesirable. Also note, that even far-field interaction design (where the control of dots effects 4 dots further), is also relatively close to the threshold, while it takes into account interaction between much more points.

It should be noted that the value of 10 MHz cited above is an estimate based on current hardware limitations. Hardware developments may reduce the required bandwidth. In general, any micromagnet configuration that reduces the distance over which the quantum dots are affected by each others control signals (cross-talk) is an improvement over current practice. In other words, all bandwidth that can be gained will lead to reduced cross-talk, and therefore reduced errors in the quantum processor. Completely localized control is, at least based on current technologies, not physically possible.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A quantum dot structure comprising:
a two-dimensional quantum dot array of quantum dots; and,
a micromagnet array comprising a plurality of micromagnets arranged in a periodic micromagnet configuration, the plurality of micromagnets forming a magnetic field comprising local maxima and local minima in a plane defined by the two-dimensional quantum dot array, wherein each of a first part of the quantum dots is located at a local maximum of the magnetic field and each of a second part of the quantum dots is located at a local minimum of the magnetic field.

2. The quantum dot structure as claimed in claim 1, wherein the magnetic field comprises saddle points in the plane defined by the two-dimensional quantum dot array, and wherein each of a third part of the quantum dots is located at a saddle point of the magnetic field.

3. The quantum dot structure as claimed in claim 2, wherein the two-dimensional quantum dot array is formed in a stack of one or more semiconductor layers arranged on a substrate, the quantum dot structure further comprising a plurality of electrodes arranged to create and/or adjust an electric field in the quantum dot structure.

4. The quantum dot structure as claimed in claim 3, wherein the plurality of electrodes is arranged to create and control qubits in the two-dimensional quantum dot array.

5. The quantum dot structure as claimed in claim 1, wherein the micromagnet configuration defines a locally rotationally symmetric array of micromagnets and wherein each quantum dot is located in a rotation center of the rotationally symmetric array of micromagnets.

6. The quantum dot structure as claimed in claim 1, wherein the micromagnet configuration is based on a wallpaper group.

7. The quantum dot structure as claimed in claim 6, wherein each fundamental domain of the wallpaper group comprises at least part of a micromagnet.

8. The quantum dot structure as claimed in claim 1, wherein the plurality of micromagnets comprises a first micromagnet generating a first magnetic field and a second micromagnet generating a second magnetic field different from the first magnetic field, such that the difference between the first and second magnetic fields is small compared to both the first and second magnetic fields.

9. The quantum dot structure as claimed in claim 1, wherein a difference in magnetic field strength between neighboring quantum dots in the two-dimensional quantum dot array is at least 0.1 mT, and is such that a difference in resonant frequency between neighboring quantum dots in the two-dimensional quantum dot array is at least 2 MHz.

10. The quantum dot structure as claimed in claim 1, wherein a decoherence gradient of a longitudinal component of the magnetic field is at most 0.1 mT/nm.

11. The quantum dot structure as claimed in claim 1, wherein the micromagnets are paramagnets comprising cobalt.

12. The quantum dot structure as claimed in claim 1, wherein the micromagnets have a width between about 10-100 nm, a length between about 10-200 nm, and a thickness between about 5-100 nm.

13. The quantum dot structure as claimed in claim 1, wherein a distance between two quantum dots in the two-dimensional quantum dot array is smaller than 200 nm.

14. The quantum dot structure as claimed in claim 1, wherein a difference in magnetic field strength between neighboring quantum dots in the two-dimensional quantum dot array is at least 0.1 mT.

15. The quantum dot structure as claimed in claim 1, wherein a difference in magnetic field strength between neighboring quantum dots in the two-dimensional quantum dot array is such that a difference in resonant frequency between neighboring quantum dots in the two-dimensional quantum dot array is at least 2 MHz.

16. The quantum dot structure as claimed in claim 6, wherein the plurality of micromagnets forming a regular triangular micromagnet grid and the micromagnet configuration being based on a p3 or a p3m1 wallpaper group.

17. The quantum dot structure as claimed in claim 6, wherein the plurality of micromagnets forming a parallelogrammatic micromagnet grid and the micromagnet configuration being based on a p2 or a pmm wallpaper group.

18. The quantum dot structure as claimed in claim 1, wherein the two-dimensional quantum dot array is formed in a stack of one or more semiconductor layers arranged on a substrate, the quantum dot structure further comprising a plurality of electrodes arranged to create and/or adjust an electric field in the quantum dot structure.

19. The quantum dot structure as claimed in claim 18, wherein the electric field is a time-varying electric field.

20. The quantum dot structure as claimed in claim 3, wherein the plurality of micromagnets comprises a first micromagnet generating a first magnetic field and a second micromagnet generating a second magnetic field different from the first magnetic field, such that the difference between the first and second magnetic fields is small compared to both the first and second magnetic fields.
